(19) United States
(12) Patent Application Publication
(10) Pub. No.: US 2025/0105379 A1
(43) Pub. Date: Mar. 27, 2025

(54) BATTERY CELL TESTING UNIT AND BATTERY CELL TESTING SYSTEM

(71) Applicant: AVL LIST GMBH, GRAZ (AT)

(72) Inventors: AUGUSTIN GILLI, GRAZ (AT); CHRISTOPH BAUMHAKL, PREMSTAETTEN (AT); MARTIN SCHWEIGER, GRAZ (AT); CHRISTOPH GLANZER, KREMS IN KAERNTEN (AT); MARKUS HORST HOEFL, ZELTWEG (AT); PETER WALENTA, GRAZ (AT); BENOIT STALIN, LE RAINCY (FR)

(73) Assignee: AVL LIST GMBH, GRAZ (AT)

(21) Appl. No.: 18/729,890

(22) PCT Filed: Jan. 19, 2023
(86) PCT No.: PCT/AT2023/060012

§ 371 Date: Jul. 18, 2024

(30) Foreign Application Priority Data
Jan. 20, 2022 (AT) A 50022/2022

(51) Int. Cl. H01M 10/42; G01R 1/04; G01R 31/36; H01M 10/48; H01M 10/617; H01M 10/6556; H01M 50/569

(52) U.S. Cl. CPC H01M 10/4285; G01R 1/0408; G01R 31/3644; H01M 10/48; H01M 10/617; H01M 10/6556; H01M 50/569

(57) ABSTRACT

A battery cell test unit includes two pressure plates, a battery cell which is clamped between the two pressure plates, a test unit housing, an electrical connection device which electrically contacts the battery cell in the test unit housing, and conditioning plates which are arranged in the test unit housing and to abut in a planar contact from opposite sides against two outward-facing surfaces of the two pressure plates during a test. The battery cell and the two pressure plates together form a test device.

### CROSS REFERENCE TO PRIOR APPLICATIONS

This application is a U.S. National Phase application under 35 U.S.C. § 371 of International Application No. PCT/AT2023/060012, filed on Jan. 19, 2023, and which claims benefit to Austrian Patent Application No. A 50022/2022, filed on Jan. 20, 2022. The International Application was published in German on Jul. 27, 2023 as WO 2023/137511A1 under PCT Article 21 (2).

### FIELD

The present invention relates to a battery cell test unit with a battery cell, two pressure plates between which the battery cell is clamped and which form a test device with the battery cell, a test unit housing, an electrical connection device via which the battery cell can be electrically contacted in the test unit housing, and a battery cell test system for or with several such battery cell test units.

### BACKGROUND

Due to the increasing electrification of road traffic, the battery is becoming an increasingly important component for maintaining mobility as an energy storage device in automotive technology. The batteries used are usually made up of several pouch cells or prismatic cells that are connected in series. The individual battery cells must be subjected to tests in order to be able to estimate durability, performance, and the resulting distances possible.

These tests usually take place in climate chambers in which the ambient temperature can be set to different temperatures. This involves running through specified temperature profiles as well as determining the resulting power and/or capacity of the battery cell at different constant temperatures.

The climate chambers usually contain high-current connectors, sensors, such as temperature sensors, and signal connectors for connecting the battery cell or the test unit, consisting of the battery cell and the pressure plates between which the battery cell is clamped, with the corresponding control and power supply, which is located outside the climate chamber. These connections must often be made manually individually.

The problem arises, however, that the growing number of battery cells to be tested means that the time required to carry out and prepare a single measurement, and the costs associated therewith, are too high. The required installation space is also too large.

### SUMMARY

An aspect of the present invention is therefore to provide a battery cell test unit and a battery cell test system with which measurements can be carried out on battery cells in a shorter time and with less set-up time. The installation space used for the tests and the costs associated therewith are thereby to be significantly reduced.

In an embodiment, the present invention provides a battery cell test unit which includes two pressure plates, a battery cell which is clamped between the two pressure plates, a test unit housing, an electrical connection device which is configured to electrically contact the battery cell in the test unit housing, and conditioning plates which are arranged in the test unit housing and to abut in a planar contact from opposite sides against two outward-facing surfaces of the two pressure plates during a test. The battery cell and the two pressure plates together form a test device.

In an embodiment, the present invention also provides a battery cell test unit which includes a battery cell, pressure plates, a test unit housing, an electrical connection, and conditioning plates. The pressure plates comprise a first pressure plate comprising surfaces comprising a first surface and a second surface each of which face outwards and which are opposite to each other, and a second pressure plate comprising surfaces comprising a first surface and a second surface each of which face outwards and which are opposite to each other. The first pressure plate and the second pressure plate are arranged so that so that the battery cell is clamped therebetween. The first pressure plate, the second pressure plate and the battery cell together form a test device. The electrical connection device is configured to electrically contact the battery cell in the test unit housing. The conditioning plates are arranged in the test unit housing. The conditioning plates comprise a first conditioning plate comprising a first side, and a second conditioning plate comprising a second side. During a test, the first side of the first conditioning plate is arranged to abut in a planer contact with the first surface of at least one of the first pressure plate and the second pressure plate, and the second side of the second conditioning plate is arranged to abut in a planer contact with the second surface of at least one of the first pressure plate and the second pressure plate.

### BRIEF DESCRIPTION OF THE DRAWINGS

The present invention is described in greater detail below on the basis of embodiments and of the drawings in which:

FIG. 1 shows a test unit of a battery cell test unit according to the present invention in a perspective view;

FIG. 2 shows a perspective view of a battery cell test unit before the test unit is moved to the test location;

FIG. 3 shows a perspective view of a battery cell test unit after the test unit has been moved to the test location; and

FIG. 4 shows a perspective view of a battery cell test system according to the present invention.

### DETAILED DESCRIPTION

The present invention provides a battery cell test unit which has a battery cell which is clamped between two pressure plates and forms a test device with these pressure plates. The battery cell test unit also has a test unit housing with an electrical connection device via which the battery cell in the test unit housing can be electrically contacted. This contact is used both for supplying voltage and for tapping signals. According to the present invention, conditioning plates are arranged in the test unit housing which, during the test, abut planar from opposite sides against two outward-facing surfaces of the pressure plates. Opposite sides are thereby understood to mean surfaces in which the normal vectors from the surfaces point in opposite directions. By placing these conditioning plates against the pressure plates, a direct thermal coupling is created between the pressure plates and the conditioning plates, and in turn from the pressure plates to the intermediate battery cell, so that the battery cell can be cooled or heated to the desired temperature very quickly, so that the entire environment need not be conditioned accordingly. The battery cell test unit itself can remain at ambient temperature. The battery cell test units can also be very small and only needs to have the electrical connection devices for contacting the sensors and the battery cell. The measurement and set-up time can thereby be significantly reduced, and the costs incurred can be accordingly also be reduced. A large number of measurements can be carried out in a small installation space.

The present invention also provides a battery cell test system in which a plurality of battery cell test units are arranged above or next to one another, the conditioning plates of at least one battery cell test unit being conditioned to a first temperature, and the conditioning plates of a second battery cell test unit being conditioned to a second temperature which differs from the first temperature. By moving the test device in and out from one battery cell test unit to a next battery cell test unit having a different temperature, the test device can be brought into a thermally conductive contact with preconditioned conditioning plates correspondingly quickly so that the corresponding temperature change during testing can also be implemented very quickly since the battery cell can be cooled or heated very quickly via the existing heat conduction.

The two outward-facing surfaces of the pressure plates, against which the conditioning plates abut planar during the test, can, for example, be narrow surfaces of the pressure plates. This has the advantage that the entire sensor system can be conveniently arranged on the broad surface of the pressure plates and a sufficient heat conduction can still be achieved.

The pressure plates can, for example, have two broad surfaces and four narrow surfaces, the four narrow surfaces forming two parallel longitudinal side surfaces and two parallel transverse side surfaces, the transverse side surfaces extending perpendicular to the longitudinal side surfaces, the conditioning plates abutting planar against the longitudinal side surfaces of the pressure plates during the test. The opposing contact with the longitudinal side surfaces enables the conditioning plates to be pressed firmly against the narrow surfaces of the pressure plates and also provides a relatively large surface for heat conduction, which can shorten the time required to condition the battery cell.

In an embodiment of the present invention, exactly four conditioning plates can, for example, be assigned to each test device, of which a first conditioning plate abuts from the first side against the first longitudinal side surface of the first pressure plate, a second conditioning plate abuts from the opposite second side against the second longitudinal side surface of the first pressure plate, a third conditioning plate abuts from the first side against the first longitudinal side surface of the second pressure plate, and a fourth conditioning plate abuts from the second side against the second longitudinal side surface of the second pressure plate. It is thereby possible to compensate for tolerances so as to provide a full-surface contact of the conditioning plates with both pressure plates in that a full-surface contact can be achieved even if the pressure plates are slightly offset from each other.

Such a structure also makes it possible for the first and second conditioning plates to have a first temperature and the third and fourth conditioning plates to have a second temperature that differs from the first temperature. A temperature gradient can therefore be set on the battery cell if desired.

In an alternative embodiment of the present invention, exactly two conditioning plates are assigned to each test device, of which a first conditioning plate abuts against the two first longitudinal side surfaces from the first side, and a second conditioning plate abuts against the two second longitudinal side surfaces of the two pressure plates from the opposite second side. This simplifies the design of the battery cell test unit in that only one actuator is required for each side to move the conditioning plates. The overall design is also simplified by reducing the number of parts.

The controllability of the temperature of the conditioning plates can also be increased by the fact that each conditioning plate has an inlet, an outlet, and an inner channel through which a conditioning medium flows from the inlet to the outlet. The temperature of the conditioning plates, and thus of the pressure plates and the battery cell, can be changed very quickly via the medium in that an optimally conditioned medium can be continuously supplied while the heated or cooled conditioning medium is removed. The inlet and outlet can, for example, be formed on the narrow surfaces. If a conditioning fluid is used, the heat conduction is additionally improved by the existing heat capacity of the fluid.

An even better heat transfer to the outer surface of the conditioning plates is achieved by forming webs in the inner channel of the conditioning plates. These webs can in particular be designed as turbulator plates.

The conditioning plates in the battery cell test unit can, for example, be moved against the surfaces of the pressure plates using a pneumatic, hydraulic, or electric actuator. Each conditioning plate is therefore assigned to a linear actuator that moves the conditioning plate against the test device. The thermal connection can accordingly be carried out automatically.

The conditioning plates are advantageously shaped to correspond to the surfaces of the pressure plates so that full-surface contact is always achieved regardless of the shape of the surfaces.

It is also advantageous if the conditioning plates are coupled to the actuator so that they can tilt. This tilting movement should be limited to a few angular degrees. If the pressure plates are not exactly aligned with the actuators, tolerances can be compensated for via slight tilting movements so that full-surface contact is still achieved.

This tilting movement of the conditioning plates in relation to the actuator can be achieved using elastic damping elements. Each conditioning plate thereby also adapts to the position of the surfaces of the pressure plates. This also achieves a full-surface contact with the resulting good heat conduction.

The conditioning plates can alternatively be tilted in relation to the actuator using a ball head connection. The pressure plate can here too tilt both vertically and horizontally around the ball head to provide a complete contact.

It is also possible to guide the conditioning plates in the battery cell test unit via linear guides which can, for example, be designed as rails. This provides an exact linear movement.

Alignment and tolerance errors of the conditioning plates relative to the retracted test unit or the pressure plates can then be compensated for by floating guiding the conditioning plates to the test unit housing.

The test unit can, for example, be moved along the direction of extension of the longitudinal side surfaces of the pressure plates via a transport device to a test location in the battery cell test unit, at which the conditioning plates can be moved against the longitudinal side surfaces of the pressure plates. This allows the test device to be moved in and positioned and the conditioning plates to be applied automatically, thereby saving time and avoiding operating errors.

It is furthermore advantageous if the electrical connection device is formed inside the battery cell test unit into which the battery cell can be moved with its connection contacts. This means that the electrical connection is established at the same time as the battery cell is automatically retracted. Here too, errors are reliably avoided and the assembly time is reduced.

In an embodiment of the present invention, a power connector can, for example, be formed on the transport device, the power connector being electrically connected to the battery cell, for example, via flexible copper tracks, and engaging in a power connector counterpart serving as an electrical connection device, which is formed on the battery cell test unit, after the transport device has been moved into the test station. This makes it easy to establish the desired electrical connection to the power supply or to the power tap.

The transport device can also have a signal connector which is electrically connected to sensors and which engages in a signal connector counterpart after the transport device has been moved to the test location, which forms the electrical connection device with the current connector counterpart, so that the signal connection can also be established at the same time as the high-current connection, whereby the entire control can be carried out from outside the battery cell test unit. The high-current connector with the signal connector can of course also be manufactured as one connector part, just like the counterparts.

The pressure plates can, for example, have holes through which screws protrude, which are used to clamp the battery cell between the pressure plates. This allows the test device to be prepared and a defined clamping force to be applied before it is inserted into the housing of the battery cell test unit.

It is also possible to move several test units one above the other into a battery cell test unit, whereby several electrical connection devices are arranged one above the other in the battery cell test unit, into which the battery cells with their connection contacts or the test units with their power connectors and/or signal connectors can be inserted. Several battery cells can thereby be tested in one battery cell test unit while the electrical connections can still be easily made. One conditioning plate and only one actuator per side can also be used with several test units stacked on top of each other.

It is also conceivable to arrange several battery cells on top of each other with one pressure plate between adjacent battery cells and to have screws protruding through the holes of all pressure plates which serve to clamp the several battery cells between the pressure plates. This simplifies the setup when testing several battery cells at the same time.

The pressure plates and/or the conditioning plates can, for example, be made of a material that has a thermal conductivity of more than 100 W/m*K. This can, for example, be aluminum or copper. These materials provide good heat conduction for fast and correct conditioning of the battery cell over its entire surface, as this heat can be quickly supplied to or dissipated from the plates via the medium.

In order to achieve a direct supply and discharge of the conditioning medium, the inlet and outlet are each connected to a conditioning unit via which the temperature of the conditioning medium can be regulated. The conditioning plate can thereby be continuously supplied with fresh conditioning medium, in particular via the narrow surfaces, and the heated or cooled conditioning medium can be fed to the conditioning unit for reprocessing.

With regard to the test system, it is advantageous that the test devices can be moved automatically via a transport system from a battery cell test unit whose conditioning plates are conditioned to the first temperature to a second battery cell test unit whose conditioning plates are conditioned to the second temperature. The conditioning in the various battery cell test units can thereby be kept constant, which saves energy as the conditioning medium can be kept at a constant level.

This provides a battery cell test unit and a battery cell test system with which a precise conditioning of the battery cells for testing can be carried out in a very small space. Temperature profiles can be run fully automatically with little control effort. The set-up time and test time can be significantly reduced compared to conventional designs. This significantly increases the efficiency of the system.

An exemplary embodiment of a battery cell test unit according to the present invention and a battery cell test system according to the present invention is shown in the drawings and is described below.

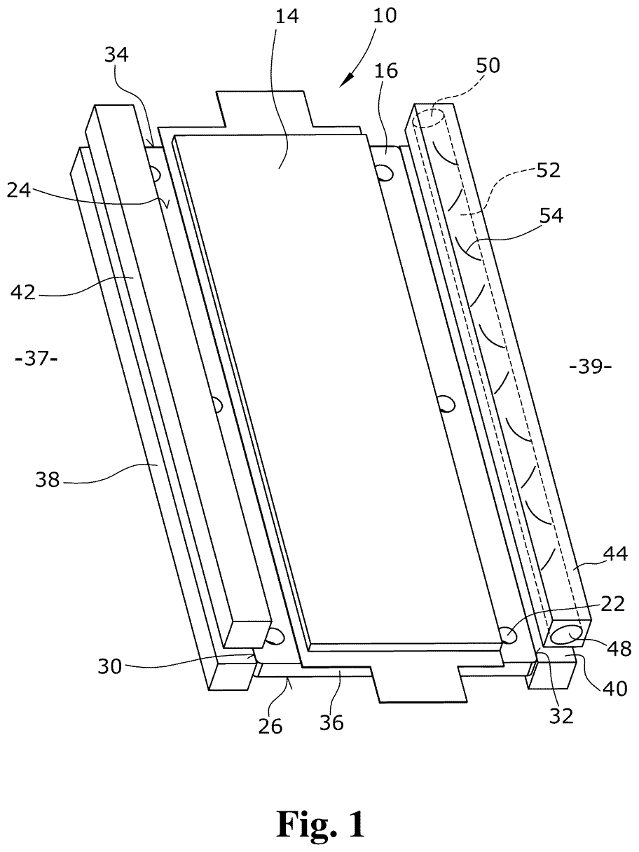

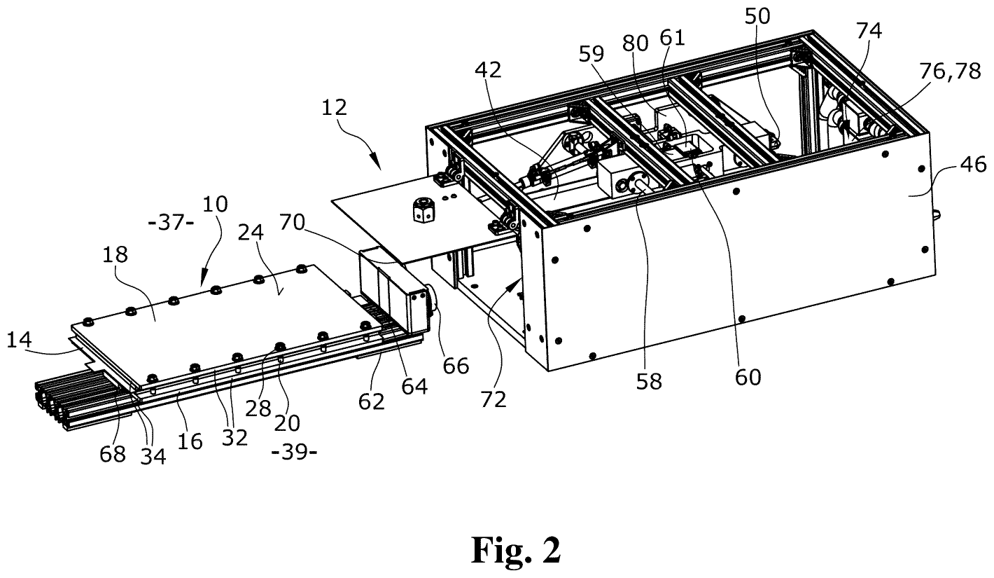

FIG. 1 shows a test device 10 of a battery cell test unit 12 according to the present invention. The battery cell test unit 12 consists of a battery cell 14, which is clamped between a first pressure plate 16 and a second pressure plate 18, which is cut away in FIG. 1. The two pressure plates 16, 18 are fastened to each other via screws 20 with the battery cell 14 interposed between, wherein the screws 20 extend through holes 22, which extend vertically through the pressure plates 16, 18, which have an identical hole pattern, from a first broad surface 24 to a second broad surface 26 formed on the opposite side. A screw nut 28 is then screwed onto the end of each screw 20 for tensioning in order to create a defined surface pressure and a good thermal connection between the pressure plates 16, 18 and the battery cell 14, as can be seen in FIG. 2. In addition to the two broad surfaces 24, 26, each pressure plate 16, 18 has four further narrow surfaces 30, 32, 34, 36, which in the present exemplary embodiment are aligned perpendicular to the two broad surfaces 24, 26 and delimit them, the two longer narrow surfaces 30, 32 form a first longitudinal side surface 30 and a second longitudinal side surface 32 parallel thereto, and the two shorter ones form a first transverse side surface 34 and a second transverse side surface 36, via which the longitudinal side surfaces 30, 32 are connected to one another and which are arranged at a 90° angle thereto.

FIG. 1 also shows that a first conditioning plate 38 abuts against the narrow first longitudinal side surface 30 of the first pressure plate 16 from a first side 37, and that a second conditioning plate 40 abuts against the second longitudinal side surface 32, which is parallel to the opposite second side 39. A third conditioning plate 42 abuts against the first longitudinal side surface 30 of the second pressure plate 18 (which is not shown), and a fourth conditioning plate 44 abuts against an opposite second longitudinal side surface 32 of the second pressure plate 18.

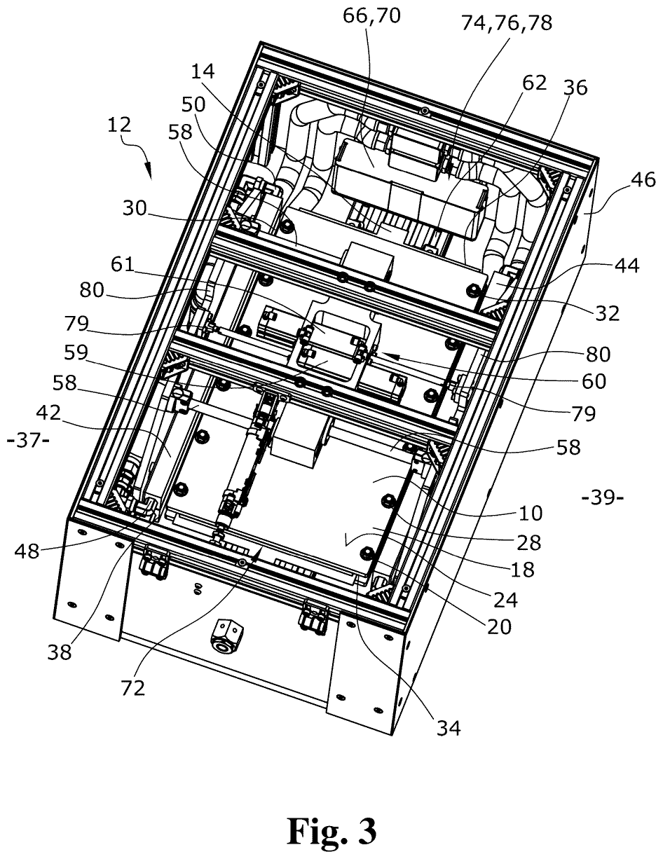

In FIG. 3, the conditioning plates 38, 40, 42, 44 are located within a test unit housing 46 which encloses a test chamber. The conditioning plates 38, 40, 42, 44 extend along the longitudinal sides of the test unit housing 46 and each have an inlet 48 and an outlet 50 on the opposite side, which are connected to each other via an inner channel 52 in each conditioning plate 38, 40, 42, 44. Webs 54 are arranged in the inner channel 52 to improve the heat transfer between a conditioning medium and the outer surface of the conditioning plates 38, 40, 42, 44. The conditioning medium, whose temperature in known tests is between −40° C. and 90° C., flows from a (not shown) conditioning unit outside the test unit housing 46 via the inlet 48 into the inner channel 52, where it transfers its heat to the surrounding conditioning plate 38, 40, 42, 44 or absorbs heat therefrom. The conditioning medium then flows back to the conditioning unit via the outlet 50.

The conditioning plates 38, 40, 42, 44 are mounted linearly movable and floatingly supported in the test unit housing 46 and are guided in the test unit housing 46 via linear guides 58. The conditioning plates 38, 40, 42, 44 are actuated via an actuator 60 via which the conditioning plates 38, 40, 42, 44 can be pulled against the longitudinal side surfaces 30, 32 of the pressure plates 16, 18. In the present embodiment, this actuator 60 has two pneumatic cylinders 59, 61, but the actuator 60 can also be actuated pneumatically, hydraulically, or electrically or by an electric motor.

The battery cell 14 is mounted with the pressure plates 16, 18 on a transport device 62 and is electrically prepared by electrically connecting the battery cell 14 to the transport device 62 by establishing a connection between the connection contacts 64 of the battery cell 14 and a power connector 66, which is formed on the transport device 62 and is moved therewith. This connection can, for example, be established using flexible copper strips. Sensors 68, such as temperature sensors, are also attached to the test device 10, the signal lines of which are connected to a signal connector 70 attached to the transport device 62.

The transport device 62 with the test device 10 attached thereto is pushed into the test unit housing 46 and to a defined test location 72 via a fully automated transport system (which is not shown in detail). By pushing the transport device 62 in, the power connector 66 and the signal connector 70 are pushed into an electrical connection device 74, which is arranged on a rear wall of the test unit housing 46 and has contact with a voltage source and an evaluation unit. By establishing this electrical connection, the end position of the transport device 62 and the reaching of the test location 72 are also defined at the same time. The electrical connection device 74 accordingly has a signal connector counterpart 76 for receiving the signal connector 70 and a power connector counterpart 78 for receiving the power connector 66 so that the electrical connection is established automatically.

After reaching the test location 72, the conditioning plates 38, 40, 42, 44 are pulled from the longitudinal sides of the test unit housing 46 against the pressure plates 16, 18 of the test device 10 via the two pneumatic cylinders 59, 61 of the pneumatic actuator 60. For this purpose, the first pneumatic cylinder 59 is connected via a ball head connection 79 to a first support structure 80, on which the two conditioning plates 38, 42 are suspended on the first side 37 of the test device 10, and the second pneumatic cylinder 61 is connected via a ball head connection 79 to a second support structure 81, on which the two conditioning plates 40, 44 are suspended on the second side 39 of the test device 10. Any alignment or tolerance errors are compensated for by the floating mounting of the conditioning plates 38, 40, 42, 44 and their mounting on the linear guide 58, via which the conditioning plates 38, 40, 42, 44 can align themselves with the pressure plates 16, 18 in order to provide the fullest possible contact with the longitudinal side surfaces 30, 32, whereby canting is prevented by the two linear guides 58 on each side.

Thermal energy is transferred from the conditioning medium via the conditioning plates 38, 40, 42, 44 to the pressure plates 16, 18 and to the battery cell 14 or dissipated therefrom by heat conduction. The full-surface press contact between the conditioning plates 38, 40, 42, 44 and the pressure plates 16, 18 creates a thermal coupling with very good heat transfer. The heat conduction within the conditioning plates 38, 40, 42, 44 and the pressure plates 16, 18 is determined by the choice of material. Aluminum is here used because it has very good thermal conductivity. The battery cell 14 can be cooled or heated to a desired temperature correspondingly quickly, which can be checked via the temperature sensor 68, so that the battery cell 14 can be individually tested thermally and electrically.

The good thermal conductivity of the pressure plates and the conditioning plates and the high specific heat capacities of the conditioning fluid compared to air make it possible to condition the battery cell efficiently and quickly. The environment of the test station also need not be cooled or heated which significantly increases the efficiency of the system. Conditioning can be carried out both via the cell surfaces and via the current conductors of the battery cell.

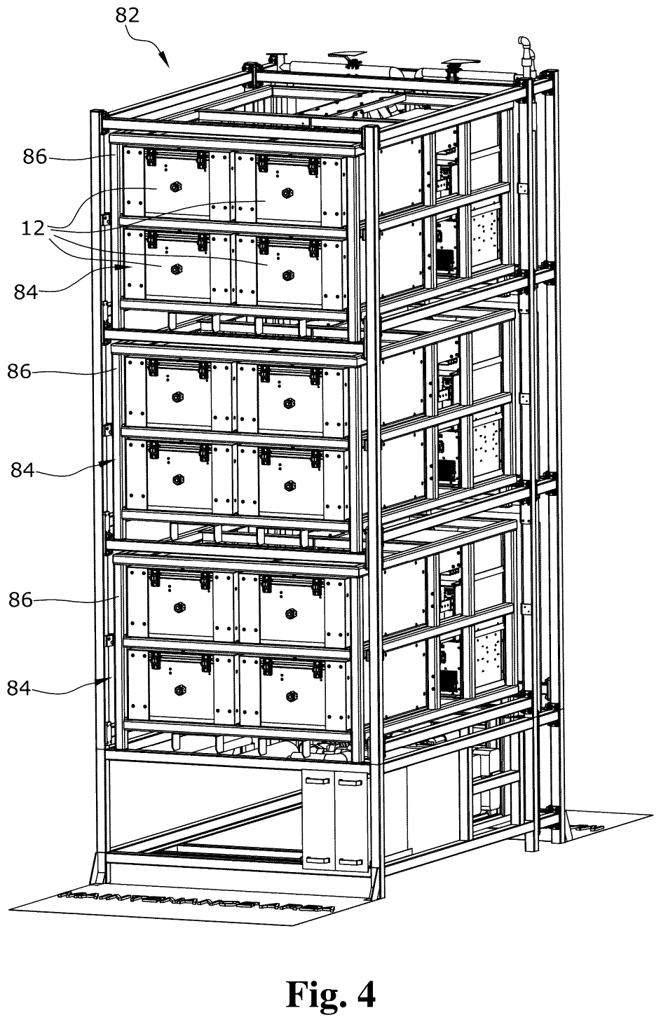

FIG. 4 shows a battery cell test system 82 according to the present invention, which comprises several battery cell test units 12 arranged one above the other and side by side. This battery cell test system 82 has three subsystems 84, each comprising four battery cell test units 12. Each subsystem 84 has its own mounting frame 86 to which the battery cell test units 12 are attached. The battery cell test system 82 includes a transport system (which is not shown) via which the battery cell test units 12 can be moved fully automatically into the corresponding test devices 10.

The conditioning of the individual battery cell test units 12 takes place via zone conditioning. The operation can then be carried out so that a different temperature is set in each battery cell test unit 12 belonging to a subsystem 84. In each further subsystem 84, these different temperatures are again defined in the associated battery cell test units 12. The temperature is accordingly not changed within a battery cell test unit 12, but the test device 10 changes the battery cell test unit 12 in the event of a temperature jump in the test run and thus follows the specified temperature profile.

It is of course also possible to subject each individual battery cell test unit 12 to a transient temperature change if required. A highly compact individual temperature control per battery cell test unit 12 is provided therefor.

This test system facilitates the automatic test sequence for testing battery cells at different temperature profiles with low energy consumption. The entire measurement process can be carried out fully automatically after the test units have been fitted.

It should be clear that various modifications are possible compared to the exemplary embodiments. For example, several stacks of battery cells and pressure plates can form a test unit, which is then electrically connected via one or more connectors. Only two conditioning plates can also be used for each test unit, which are then pushed against the superimposed surfaces of all the pressure plates in order to condition them. The conditioning plates can also abut against the broad surfaces of the pressure plates.

The present invention is not limited to embodiments described herein; reference should be had to the appended claims.

### LIST OF REFERENCE NUMERALS

10 Test device
12 Battery cell test unit
14 Battery cell
16 First pressure plate
18 Second pressure plate
20 Screw
22 Hole
24 First broad surface
26 Second broad surface
28 Screw nut
30 First longitudinal side surface/Narrow surface
32 Second longitudinal side surface/Narrow surface
34 First transverse side surface/Narrow surface
36 Second transverse side surface/Narrow surface
37 First side
38 First conditioning plate
39 Second side
40 Second conditioning plate
42 Third conditioning plate
44 Fourth conditioning plate
46 Test unit housing
48 Inlet
50 Outlet
52 Inner channel
54 Web
58 Linear guide
59 First pneumatic cylinder
60 Actuator
61 Second pneumatic cylinder
62 Transport device
64 Connection contact
66 Power connector
68 Sensor/Temperature sensor
70 Signal connector
72 Test location
74 Electrical connection device
76 Signal connector counterpart
78 Power connector counterpart
79 Ball head connection
80 First support structure
82 Battery cell test system
84 Subsystem
86 Mounting frame

What is claimed is:

1-26 (Canceled)

27. A battery cell test unit comprising:
two pressure plates;
a battery cell which is clamped between the two pressure plates, the battery cell and the two pressure plates together forming a test device;
a test unit housing;
an electrical connection device which is configured to electrically contact the battery cell in the test unit housing; and
conditioning plates which are arranged in the test unit housing and to abut in a planar contact from opposite sides against two outward-facing surfaces of the two pressure plates during a test.

28. A battery cell test unit comprising:
a battery cell;
pressure plates comprising,
a first pressure plate comprising surfaces comprising a first surface and a second surface each of which face outwards and which are opposite to each other, and
a second pressure plate comprising surfaces comprising a first surface and a second surface each of which face outwards and which are opposite to each other, the first pressure plate and the second pressure plate being arranged so that so that the battery cell is clamped therebetween, the first pressure plate, the second pressure plate and the battery cell together forming a test device;
a test unit housing;
an electrical connection device which is configured to electrically contact the battery cell in the test unit housing; and
conditioning plates arranged in the test unit housing, the conditioning plates comprising a first conditioning plate comprising a first side, and a second conditioning plate comprising a second side,
wherein, during a test,
the first side of the first conditioning plate is arranged to abut in a planer contact with the first surface of at least one of the first pressure plate and the second pressure plate, and
the second side of the second conditioning plate is arranged to abut in a planer contact with the second surface of at least one of the first pressure plate and the second pressure plate.

29. The battery cell test unit as recited in claim 28, wherein,
only the first conditioning plate and the second conditioning plate are assigned to each test device,
the first surface of each of the first pressure plate and the second pressure plate is a first longitudinal side surface,
the second surface of each of the first pressure plate and the second pressure plate is a second longitudinal side surface,
the first conditioning plate abuts against the first longitudinal side surface of each of the first pressure plate and the second pressure plate, and
the second conditioning plate abuts against the second longitudinal side surface of each of the first pressure plate and the second pressure plate.

30. The battery cell test unit as recited in claim 28, wherein,
the first surface and the second surface of the first pressure plate is provided as a narrow surface, and
the first surface and the second surface of the second pressure plate is provided as a narrow surface.

31. The battery cell test unit as recited in claim 28, wherein,
the surfaces of the first pressure plate further comprises a first broad surface, a second broad surface, and four narrow surfaces, the four narrow surfaces comprising,
a first longitudinal side surface as the first surface and a second longitudinal side surface as the second surface, the first longitudinal side surface and the second longitudinal side surface being parallel with respect to each other, and
a first traverse side surface and a second traverse side surface, the first traverse side surface and the second traverse side surface facing outwards, being opposite to each, and being parallel with respect to each other, and
the surfaces of the second pressure plate further comprises a first broad surface, a second broad surface, and four narrow surfaces, the four narrow surfaces comprising,
a first longitudinal side surface as the first surface and a second longitudinal side surface as the second surface, the first longitudinal side surface and the second longitudinal side surface being parallel with respect to each other, and
a first traverse side surface and a second traverse side surface, the first traverse side surface and the second traverse side surface facing outwards, being opposite to each, and being parallel with respect to each other.

32. The battery cell test unit as recited in claim 31, wherein,
the conditioning plates further comprise a third conditioning plate comprising a third side, and a fourth conditioning plate comprising a fourth side,
exactly four conditioning plates consisting of the first conditioning plate, the second conditioning plate, the third conditioning plate, and the fourth conditioning plate are used during the test, and
during the test,
the first side of the first conditioning plate is arranged to abut in the planer contact with the first longitudinal side surface of the first pressure plate,
the second side of the second conditioning plate is arranged to abut in the planer contact with the second longitudinal side surface of the first pressure plate,
the third side of the third conditioning plate is arranged to abut in a planer contact with the first longitudinal side surface of the second pressure plate, and
the fourth side of the fourth conditioning plate is arranged to abut in a planer contact with the second longitudinal side surface of the second pressure plate.

33. The battery cell test unit as recited in claim 32, wherein,
the first conditioning plate and the second conditioning plate are provided to have a first temperature, and
the third conditioning plate and the fourth conditioning plate are provided to have a second temperature which is different from the first temperature.

34. The battery cell test unit as recited in claim 28, wherein each of the conditioning plates further comprises an inlet, an outlet, and an inner channel which is configured so that a conditioning medium can flow from the inlet to the outlet.

35. The battery cell test unit as recited in claim 34, wherein the inlet and the outlet are each connected to a conditioning unit which is configured to regulate a temperature of the conditioning medium.

36. The battery cell test unit as recited in claim 34, wherein webs are formed in each inner channel of the conditioning plates.

37. The battery cell test unit as recited in claim 28, further comprising:
an actuator which is configured to move the conditioning plates in the battery cell test unit against a respective pressure plate of the pressure plates,
wherein,
the actuator is a pneumatic actuator, a hydraulic actuator or an electric actuator.

38. The battery cell test unit as recited in claim 37, wherein the conditioning plates are coupled to the actuator so as to be tiltable.

39. The battery cell test unit as recited in claim 38, further comprising:
elastic damping elements which are configured to provide a tilting movement of the conditioning plates relative to the actuator.

40. The battery cell test unit as recited in claim 38, further comprising:
a ball head connection which is configured to provide a tilting movement of the conditioning plates relative to the actuator.

41. The battery cell test unit as recited in claim 28, wherein the conditioning plates are shaped to correspond to the surfaces of the pressure plates.

42. The battery cell test unit as recited in claim 28, further comprising:
a linear guide which is configured to guide the conditioning plates in the battery cell test unit.

43. The battery cell test unit as recited in claim 41, wherein the conditioning plates are configured to be floatingly guided to the test unit housing.

44. The battery cell test unit as recited in claim 28, wherein,
the first surface of each of the first pressure plate and the second pressure plate is a first longitudinal side surface,
the second surface of each of the first pressure plate and the second pressure plate is a second longitudinal side surface, and
the test device is configured to be moved along a direction of extension of the first longitudinal side surface and of the second longitudinal side surface of the first pressure plate and of the second pressure plate via a transport device to a test location in the battery cell test unit, and
the first conditioning plate is movable against the first longitudinal side surface and the second conditioning plate is movable against the second longitudinal side surface at the test location.

45. The battery cell test unit as recited in claim 44, further comprising:
a power connector formed at the transport device; and
a power connector counterpart formed at the battery cell test unit, the power connector counterpart being configured to serve as the electrical connection device,
wherein,
the power connector is electrically connected to the battery cell and, after the transport device has been moved to the test location, is configured to engage in the power connector counterpart.

46. The battery cell test unit as recited in claim 45, further comprising:
sensors,
wherein,
the electrical connection device further comprises a signal connector counterpart and a current connector counterpart, and
the transport device comprises a signal connector which is electrically connected to the sensors and which, after the transport device has been moved to the test location, engages in the signal connector counterpart.

47. The battery cell test unit as recited in claim 46, wherein,
the battery cell comprises connection contacts,
the electrical connection device is formed inside the battery cell test unit, and
the battery cell with its connection contacts is configured to be movable into the battery cell test unit.

48. The battery cell test unit as recited in claim 47, wherein,
a plurality of the test devices are arranged to be movable one above the other into the battery cell test unit, and
a plurality of the electrical connection devices are arranged one above the other in the battery cell test unit and are configured so that the connection contacts of the battery cells or at least one of the power connectors and the signal connectors of the test devices are insertable thereinto.

49. The battery cell test unit as recited in claim 28, wherein the pressure plates comprise holes through which screws protrude so that the battery cell is clampable between the pressure plates.

50. The battery cell test unit as recited in claim 28, wherein,
a plurality of the battery cells are arranged one above the other with one of the pressure plates interposed between each adjacent battery cell, and
each of the pressure plates comprise holes through which screws protrude which serve to clamp the plurality of battery cells between the pressure plates.

51. The battery cell test unit as recited in claim 28, wherein at least one of the pressure plates and the conditioning plates are made of a material which has a thermal conductivity of more than 100 W/m*K.

52. A battery cell test system comprising:
a plurality of the battery cell test units as recited in claim 28 which are arranged above or next to one another,
wherein,
the conditioning plates of at least a first battery cell test unit of the plurality of battery cell test units are conditioned to a first temperature,
the conditioning plates of at least a second battery cell test unit of the plurality of battery cell test units are conditioned to a second temperature, and
the first temperature is different from the second temperature.

53. The battery cell test system as recited in claim 52, further comprising:
a transport system which is configured to automatically move the test devices from a battery cell test unit whose conditioning plates are conditioned to the first temperature into a second battery cell test unit whose conditioning plates are conditioned to the second temperature.
